(19) United States
(12) Patent Application Publication
(10) Pub. No.: US 2006/0022309 A1
(43) Pub. Date: Feb. 2, 2006

(54) Surface protective film

(75) Inventors: Hisatsugu Tokunaga, Gunma (JP); Atsushi Takei, Guma (JP); Mikio Shimizu, Gunma (JP)

Correspondence Address: YOUNG & THOMPSON, 745 SOUTH 23RD STREET, 2ND FLOOR, ARLINGTON, VA, 22202, US

(73) Assignee: Denki Kagaku Kogyo Kabushiki Kaisha, Tokyo 100-8455 (JP)

(21) Appl. No.: 10/538,035

(22) PCT Filed: Dec. 9, 2003
(86) PCT No.: PCT/JP03/15743

§ 371 Date: Jun. 8, 2005

(30) Foreign Application Priority Data
Dec. 12, 2002 (JP) 2002-360207
Dec. 18, 2002 (JP) 2002-366139
Dec. 19, 2002 (JP) 2002-367864
Dec. 26, 2002 (JP) 2002-375798

(51) Int. Cl. H01L 23/58

(52) U.S. Cl. 257/632

(57) ABSTRACT

A surface protective film includes a substrate film having formed on one surface a coating film selected from (1) a coating film of a nonionic surfactant having a hydrophilic-lipophilic balance (HLB) of 13 or more, (2) a coating film of a surfactant including an ammonium salt of a fluorine based phosphoric acid ester, (3) a coating film of dimethyl silicone oil, and (4) a coating film of a mixture of a water-soluble urethane resin and dimethyl silicone. The protective film is excellent in antistaining property and ink adhesiveness. The substrate film preferably includes a thermoplastic resin. The pressure-sensitive adhesive may be acrylic, urethane based, rubber based, or silicone based. Adhesives having high transparency are preferable, and acrylic pressure-sensitive adhesives are preferable for their adhesive characteristics. The antistaining property and ink adhesiveness make it suitable for surface protection of polarizing plates, liquid crystal displays, plasma displays, etc.

### TECHNICAL FIELD

The present invention relates to a surface protective film. In particular, the invention relates to a surface protective film comprising a substrate film having a specific coating film formed on one surface thereof

### BACKGROUND ART

A surface protective film is adhered on the surface of a member, thereby protecting the surface of the member. Specific examples of such a surface protective film include a surface protective film for polarizing plate. In a polarizing plate that is used on the outermost surface of a liquid crystal panel, for the sake of preventing damages in the distribution step or assembling step of liquid crystal displays, a surface protective film having been subjected to pressure-sensitive adhesive processing is adhered on the film surface. In the manufacture step of polarizing plate, an pressure-sensitive adhesive coated on the back surface of the polarizing plate, finger marks, fingerprints or other stains may possibly be adhered to the surface protective film. A contamination control performance such that these stains can be easily wiped is required.

There is a measure for forming a contamination control layer on the surface of a surface protective film such that adhesion of stains can be prevented or adhered stains can be easily removed. Such a measure is disclosed in, for example, JP-A-6-256756, JP-B-6-29332, JP-A-9-113726, JP-A-11-256115, JP-A-12-321423, JP-A-2001-96698 and JP-A-2001-305346. Of those, JP-A-9-113726, JP-A-11-256115, JP-A-12-321423 and JP-A-2001-96698 disclose a measure of providing a layer made of a fluorine compound or a long chain alkyl based compound.

In the quality inspection of polarizing plate, marks are often put by an ink, etc., on the surface of the surface protective film. In that case, different from the above-described stains, there is required a performance opposite the contamination control performance such that the ink spreads well and does not drop even when wiped by slightly rubbing.

### DISCLOSURE OF THE INVENTION

In view of the above requirement, the invention has been made, and an object of the invention is to provide a novel surface protective film.

The invention is concerned with a surface protective film comprising a substrate film having formed on one surface thereof a coating film selected from the group consisting of (1) a coating film of a nonionic surfactant having a hydrophilic-lipophilic balance (hereinafter simply referred to as “HLB”) of 13 or more, (2) a coating film of a surfactant comprising an ammonium salt of a fluorine based phosphoric acid ester, (3) a coating film of dimethyl silicone oil, and (4) a coating film of a mixture of a water-soluble urethane resin and dimethyl silicone.

### BEST MODE FOR CARRYING OUT THE INVENTION

Constitution

The surface protective film of the invention basically has a constitution comprising a substrate film having a specific coating film formed on one surface thereof The surface protective film can have a constitution of specific coating film/substrate film/pressure-sensitive adhesive layer, in which an pressure-sensitive adhesive is coated on the opposite surface of the substrate film to the coating film. An interlayer may be present between the substrate film and the pressure-sensitive adhesive layer. Further, a releasable film may be adhered on the surface (exposed surface) of the pressure-sensitive adhesive layer.

Substrate Film

Although the substrate film to be used in the invention is not particularly limited, it is preferably comprised of a thermoplastic resin. Examples of thermoplastic resins include polyester based resins, polystyrene based resins, polyolefin based resins, polycarbonate based resins, acrylic resins, polyamide based resins, polyurethane based resins, polyvinyl chloride based resins, epoxy based resins, phenol based resins, and alloys thereof of those, polyester films are preferably used taking into consideration nerve, presence or absence of film deformation during peeling the surface protective film, easiness in handling, etc.

Although it is preferable that the substrate film is of a single layer, the substrate film may be multilayered. The substrate film has a thickness (total thickness in the multilayered case) of from 10 to 200 μm, preferably from 10 to 100 μm, and more preferably from 20 to 50 μm.

The substrate film may be subjected to antistatic treatment, treatment for easy adhesion, etc., on the surface so far as formation of the specific coating film is not obstructed.

Coating Film

Coating agents for forming the coating film according to the invention are all soluble in water. Accordingly, a diluent in the coating agent is basically water. However, for the sake of enhancing wettability or drying efficiency of the coating agent against the substrate film, there may be the case where an organic solvent such as isopropyl alcohol is, for example, added in an amount of 10% or less by weight to the diluent.

The coating film after drying preferably has a thickness of from 1 to 500 nm, and more preferably from 10 to 200 nm.

Nonionic Surfactant:

The nonionic surfactant to be used in the invention has an HLB of 13 or more, preferably from 13 to 18, and more preferably from 14 to 18.

HLB is a value to show the ratio of the hydrophilic segment to the lipophilic segment in one molecule of the nonionic surfactant. When the amount of a hydrophilic group in the molecule is 0%, HIB is 0; when it is 100%, HLB is 20; and when the hydrophilic group is equivalent to a lipophilic group, HIB is 10. Namely, it is meant that when HLB is large, the hydrophilicity is large, whereas when HLB is small, the lipophilicity is large.

Examples of such nonionic surfactants include fatty acid esters, alkyl diethanolamines, and alkyl diethanolamides. It is preferable to use a fatty acid ester from the standpoint that HLB can be easily adjusted. Examples of fatty acid esters include esters of palmitic acid, stearic acid, lauric acid, olefic acid, linolic acid, linoleic acid, arachidic acid, etc., but it should be construed that the invention is not particularly limited thereto. Further, glycerin fatty acid esters, sucrose fatty acid esters, sorbitan fatty acid esters, polyglycerin fatty acid esters, etc. can also be used. Of those, sucrose fatty acid esters, HLB of which can be adjusted depending upon the monoester content, and polyglycerin fatty acid esters, HLB of which can be adjusted depending upon the degree of polymerization of glycerin and the kind of a fatty acid to be bound, are preferable.

These nonionic surfactants can be used alone or as mixture of two or more thereof so far as the HLB value falls with the above range.

If desired and necessary, the nonionic surfactant can contain an additive. The additive that can be contained and the amount thereof are not particularly limited so far as the coating film performance of the nonionic surfactant is not obstructed. For example, ultraviolet light absorbers, antioxidants, antistatic agents, etc., are enumerated.

Coating Method of Nonionic Surfactant:

A method of coating the nonionic surfactant on the substrate film surface can be general coating methods such as a roll coating method by generalized coating equipment such as a gravure coater, an air knife coater, a fountain die coater, and a lip coater; a mist method in which the substrate film is passed through the nonionic surfactant sprayed in the mist-like state to form a thin film on the substrate film surface; a spraying method; and a bar coating method. During coating the nonionic surfactant on the substrate film surface, the nonionic surface may be used after properly diluting with a solvent.

The film of the nonionic surfactant preferably has a thickness of from 1 to 500 nm, and more preferably from 10 to 200 nm. So far as the film thickness falls within this range, the same or two or more different kinds of nonionic surfactants can be repeatedly coated on the substrate film to form a laminated film.

For the purpose of modifying the wetting characteristic of the substrate film surface on which the nonionic surfactant is coated, the substrate film surface may be subjected to corona discharge treatment, chemical treatment, irradiation treatment with ultraviolet light, or the like. Surfactant comprising ammonium salt of fluorine based phosphoric acid ester:

The surfactant comprising an ammonium salt of a fluorine based phosphoric acid ester that is used in the invention is one made of an ammonium salt of a fluorine based phosphoric acid ester itself or one made of an ammonium salt of a fluorine based phosphoric acid ester as the major component and additives such as other surfactants, ultraviolet light absorbers, antioxidants, and antistatic agents. The proportion of the ammonium salt of a fluorine based phosphoric acid ester is preferably 50% by weight or more, and more preferably 80% by weight or more, in the components other than a volatile matter such as solvents.

The surfactant comprising an ammonium salt of a fluorine based phosphoric acid ester is preferably ones having a low molecular weight (about 2,000 or lower) and low cohesion.

The “low cohesion” as referred to herein is defined as an index showing that the pressure-sensitive adhesive strength between the surfactant and the substrate film is larger than the cohesive strength of the surfactant layer itself when an pressure-sensitive adhesive tape of Nichiban Co., Ltd. (Cellotape (registered trademark) CT405A-24) is adhered to a film of the surfactant coated and dried on the substrate film in the method according to JIS Z0237 and subjected to 180° peeling at a rate of 300 mm/min, and the surfactant component is then detected on the coating surface of the film and on the pressure-sensitive adhesive tape surface. For identification of the component, a surface analysis method such as infrared spectrophotometry may be employed, but it should not be construed that the invention is limited thereto. In the evaluation, when a surfactant whose transfer into the pressure-sensitive adhesive tape is confirmed is coated on the surface, a film that further has contamination control properties and is excellent in surface adhesion of ink can be obtained. Coating method of surfactant comprising ammonium salt of fluorine based phosphoric acid ester:

For coating the surfactant comprising an ammonium salt of a fluorine based phosphoric acid ester on the substrate film surface, conventional coating methods can be employed. A roll coating method by generalized coating equipment such as a gravure coater, an air knife coater, a fountain die coater, and a lip coater; a mist method in which the substrate film is passed through the surfactant sprayed in the mist-like state to form a film on the substrate film surface; a spraying method; a bar coating method; and the like can be applied. The surfactant is coated on the film, and if a non-volatile matter such as solvents is present, it is dried and eliminated, thereby obtaining a coating film. It is preferable that the coating film after drying has a thickness of from 1 to 500 nm.

So far as the film thickness falls within this range, the same or two or more different kinds of surfactants comprising an ammonium salt of a fluorine based phosphoric acid ester can be repeatedly coated on the substrate film to form a laminated film.

For the purpose of modifying the wetting characteristic of the substrate film surface on which the surfactant comprising an ammonium salt of a fluorine based phosphoric acid ester is coated, the substrate film surface may be subjected to corona discharge treatment, chemical treatment, or irradiation treatment with ultraviolet light.

Dimethyl Silicone Oil:

Although dimethyl silicone oil is not particularly limited, a silicone emulsion prepared by emulsifying dimethyl silicone oil can be suitably used. It is preferable that dimethyl silicone oil has low cohesion as defined previously.

Coating Method of Dimethyl Silicone Oil:

For coating dimethyl silicone oil or its emulsion on the substrate film surface, conventional coating methods can be employed. Examples include roll coating methods by generalized coating equipment such as a gravure coater, an air knife coater, a fountain die coater, and a lip coater. In the case of the emulsion, a mist method in which the substrate film is passed through the emulsion sprayed in the mist-like state to form a film on the substrate film surface; a spraying method; a bar coating method; and the like can be applied. Dimethyl silicone oil or its emulsion is applied to the substrate film, and if a non-volatile matter such as solvents is present, it is dried and eliminated, thereby obtaining a coating film. It is preferable that the coating film after drying has a thickness of from 1 to 500 nm.

So far as the film thickness falls within this range, the same or two or more different kinds of dimethyl silicone oil or its emulsion can be repeatedly coated on the substrate film to form a laminated film.

For the purpose of modifying the wetting characteristic of the substrate film surface on which dimethyl silicone oil or its emulsion is coated, the substrate film surface may be subjected to corona discharge treatment, chemical treatment, or irradiation treatment with ultraviolet light.

Mixture of Water-Soluble Urethane Resin and Dimetbyl Silicone:

It is possible to adjust the ratio of the water-soluble urethane resin to dimethyl silicone depending upon the application. For example, in the case of use as a surface protective film for polarizing plate, it is preferable that the proportion of the water-soluble urethane resin is in the range of from 0.1 to 20 times by weight based on the dimethyl silicone. In the case of enhancing adhesion to the substrate film, it is desirable that the proportion of the water-soluble urethane resin is high. In the case of enhancing the contamination control performance, it is desirable that the proportion of dimethyl silicone is high. It is preferable that the film made of a water-soluble urethane resin and dimethyl silicone has low cohesion as defined previously.

Coating Method of Mixed Liquid of Water-Soluble Urethane Resin and Dimethyl Silicone:

There are no particular limitations with respect to the method of forming a film made of a water-soluble urethane and dimethyl silicone on the substrate film surface. For example, a mixed liquid of an emulsion of a water-soluble urethane resin and an emulsion of dimethyl silicone can be applied to the substrate film by conventional coating methods. Examples of the coating method include roll coating methods by generalized coating equipment such as a gravure coater, an air knife coater, a fountain die coater, and a lip coater. A mist method in which the substrate film is passed through the mixed liquid of emulsions sprayed in the mist-like state to form a film on the substrate film surface; a spraying method; a bar coating method; and the like can also be applied. The mixed liquid is coated on the film, and if a non-volatile matter such as solvents is present, it is dried and eliminated, thereby obtaining a coating film. It is preferable that the coating film after drying has a thickness of from 1 to 500 nm.

So far as the film thickness falls within this range, the same or two or more different kinds of mixed liquids can be repeatedly coated on the substrate film to form a laminated film.

For the purpose of modifying the wetting characteristic of the substrate film surface on which the mixed liquid is coated, the substrate film surface may be subjected to corona discharge treatment, chemical treatment, or irradiation treatment with ultraviolet light.

Pressure-Sensitive Adhesive Layer

As the pressure-sensitive adhesive constituting the pressure-sensitive adhesive layer formed on the opposite surface of the substrate film to the coating film surface, for example, acrylic, urethane based, rubber based, or silicone based pressure-sensitive adhesives can be used. Pressure-sensitive adhesives having high transparency are preferable, and acrylic pressure-sensitive adhesives are preferable from the standpoint of easiness in adjustment of pressure-sensitive adhesive characteristics. For the purpose of imparting proper tackiness, the pressure-sensitive adhesive may contain a tackifier. Examples of tackifiers include rosin based, terpene based, coumarone based, phenol based, styrene based, and petroleum based resins.

The acrylic pressure-sensitive adhesive is comprised of an acrylic polymer containing an acrylic acid alkyl ester as the major component and obtained by copolymerizing it with a polar monomer component. The acrylic acid alkyl ester is an acrylic acid or methacrylic acid alkyl ester and is not particularly limited. Examples include ethyl acrylate, isopropyl acrylate, n-butyl acrylate, isobutyl acrylate, pentyl (meth)acrylate, 2-ethylhexyl (meth)acrylate, isooctyl (meth)acrylate, isononyl (meth)acrylate, decyl (meth)acrylate, and lauryl (meth)acrylate.

Examples of the polar monomer component include monomers containing a carboxyl group or a hydroxyl group such as acrylic acid, maleic anhydride, and 2-hydroxyethyl (meth)acrylate. The polar monomer becomes a functional group in the acrylic polymer.

The acrylic pressure-sensitive adhesive is used as an acrylic pressure-sensitive adhesive composition upon compounding with a crosslinking agent capable of crosslinking the acrylic polymer. Examples of crosslinking agents include polyisocyanate-based compounds such as aliphatic diisocyanates, aromatic diisocyanates, and aromatic triisocyanates. Further, for ones having slow crosslinking reaction, a crosslinking accelerator comprising an organometallic compound, etc., can be added.

Plasticizer:

A plasticizer can be added to the pressure-sensitive adhesive. Examples of plasticizers include adipic acid ester based, glycol ester based, sebacic acid ester based, trimellitic acid ester based, pyromellitic acid ester based, phthalic acid ester based, and phosphoric acid ester based plasticizers. In the case of use for the acrylic pressure-sensitive adhesive, phthalic acid ester based plasticizers are preferable, but it should not be construed that the invention is limited thereto.

The amount of the plasticizer to be compounded varies depending upon the application of the surface protective film, the kind of the pressure-sensitive adhesive, etc. In particular, in the case of use for surface protection of a polarizing plate as a preferred application of the surface protective film, it is desired to compound the plasticizer in an amount such that the 180° peeling strength is from 0.01 to 0.3 N/25 mm at a peeling rate of 300 mm/min and from 0.1 to 0.5 N/25 mm at a peeling rate of 5,000 mm/min, respectively, and the initial peeling strength is from 1.0 to 2.5 N/5 mm-diameter against a polarizing plate of Ra=390 nm and that the haze falls within the range of not more than 5% when stuck to a polarizing plate of Ra=390 nm. In these ranges, in a display using a polarizing plate, even when the surface protective film is stuck to the polarizing plate, it is easy to adjust the display, and when the surface protective film becomes unnecessary, it can be easily peeled away.

In the case where a phthalic acid ester based plasticizer is added to the acrylic pressure-sensitive adhesive, it is preferable that the amount of the plasticizer is in the range of from 5 to 25 parts by weight based on 100 parts by weight of the solids content of the acrylic pressure-sensitive adhesive.

Coating Method of Pressure-Sensitive Adhesive:

For coating the pressure-sensitive adhesive on the opposite surface of the substrate film to the coating film, conventional screen method, gravure method, mesh method, bar coating method, etc., can be applied, but it should not be construed that the invention is limited thereto. Although the thickness of the coated pressure-sensitive adhesive is not particularly limited, the thickness after drying is from 1 to 100 μm, preferably from 5 to 50 μm, and more preferably from 10 to 30 μm.

Interlayer

The interlayer that is optionally provided between the substrate film and the pressure-sensitive adhesive layer is an antistatic layer or a layer for easy adhesion (undercoat layer treated such that a liquid (such as an pressure-sensitive adhesive) to be coated on the film can be coated without causing repelling).

Releasable Film

A releasable film can be adhered on the surface (exposed surface) of the pressure-sensitive adhesive layer of the surface protective film. As the releasable film, for example, films whose surfaces have been treated with a silicone based releasing agent or other releasing agent and films having releasing properties themselves can be employed. The thickness of the releasable film is preferably from about 10 to 100 μm. The surface protective film having a releasable film adhered thereto can be wound up and stored and is convenient in transportation. The surface protective film having a release film is used after peeling away the release film and adhering the pressure-sensitive adhesive layer to the surface of a material to be protected such as a polarizing plate. An antistatic substance can be coated on the surface of the releasable film. The antistatic substance is not particularly limited so far as it has excellent adhesion to the back surface (the surface not subjected to release treatment) of the releasable film. It is preferable to chose an antistatic substance such that the surface resistance value measured according to JIS K6911 is 1.0×10¹² Ω/square or lower.

The surface protective film of the invention can be suitably used for surface protection of various members. Especially, it can be suitably used for surface protection of polarizing plates, liquid crystal displays, plasma displays, etc.

For example, the surface protective film stuck to a liquid crystal panel is finally peeled away. During this, a pressure-sensitive adhesive tape such as a cellophane pressure-sensitive adhesive tape is stuck onto the coating film surface of the surface protective film, and the cellophane pressure-sensitive adhesive tape is pulled, whereby the protective film is peeled away from the protective film. Accordingly, it is preferable that the coating film of the surface protective film can adhere the cellophane pressure-sensitive adhesive tape. Specifically, it is preferable that the peeling strength between the coating film and the cellophane pressure-sensitive adhesive tape is 400 g/24 mm or more.

### EXAMPLES

The invention will be more specifically described below with reference to the Examples, but it should not be construed that the invention is limited to these Examples.

All pressure-sensitive adhesive solutions used in the following Examples and Comparative Examples are of a solvent-diluting type. The diluting solvent varies depending upon the pressure-sensitive adhesive grade but is toluene, ethyl acetate or methyl ethyl ketone, or a mixed solution of at least two of those. Further, in coating the pressure-sensitive adhesive, the pressure-sensitive adhesive is diluted with such solvents to a viscosity such that it is easily coated. However, since the viscosity varies depending upon the pressure-sensitive adhesive grade, a degree of dilution is also different.

### Example 1

An pressure-sensitive adhesive solution of 100 parts of an acrylic pressure-sensitive adhesive (SK-DYNE 1496, manufactured by Soken Chemical & Engineering Co., Ltd.) having 0.8 parts by weight of a curing agent (D-90, manufactured by Soken Chemical & Engineering Co., Ltd.) and 0.08 parts by weight of an accelerator (ACCELERATOR-S, manufactured by Soken Chemical & Engineering Co., Ltd.) mixed therewith was coated on the antistatic treated surface of an antistatic polyester based film having a thickness of 38 μm (T100° C., manufactured by Mitsubishi Polyester Film Corporation) using a bar coater and dried at 100° C. for one minute. The pressure-sensitive adhesive layer after drying had a thickness of about 18 μm. Further, a releasable film (MRF-25, manufactured by Mitsubishi Polyester Film Corporation) having a thickness of 25 μm was adhered to the surface (exposed surface) of the pressure-sensitive adhesive layer.

A sucrose fatty acid ester having an HLB value of 15 (RIKEMAL, manufactured by Riken Vitamin Co., Ltd.) was coated in a thickness of coating film after drying of 20 nm on the opposite surface of the substrate film to the pressure-sensitive adhesive-coated surface using a gravure roll coater.

### Example 2

A polyglycerin fatty acid ester having an HLB value of 16 (POEM J-0021, manufactured by Riken Vitamin Co., Ltd.) was coated in a thickness of coating film after drying of 30 nm on one surface of a polyester based film having a thickness of 38 μm (PET-SL, manufactured by Teijin DuPont Films Japan Limited) using a gravure roll coater and heated at a temperature of 100° C. for several seconds to eliminate the diluting solvent.

A pressure-sensitive adhesive solution of 100 parts of an acrylic pressure-sensitive adhesive (SK-DYNE 1473H, manufactured by Soken Chemical & Engineering Co., Ltd.) having 1.0 part by weight of a curing agent (CORONATE L-45, manufactured by Nippon Polyurethane Industry Co., Ltd.) mixed therewith was coated on the opposite surface of the substrate film to the coating film surface using a bar coater. After drying at 100° C. for one minute, the pressure-sensitive adhesive layer had a thickness of about 10 μm. Further, a releasable film (MRF-25, manufactured by Mitsubishi Polyester Film Corporation) having a thickness of 25 μm was adhered to the surface (exposed surface) of the pressure-sensitive adhesive layer.

### Comparative Example 1

A diglycerin fatty acid ester having an HLB value of 7 (RIKEMAL DXO-100, manufactured by Riken Vitamin Co., Ltd.) was coated on one surface of a polyester based film having a thickness of 38 μm (PET-SL, manufactured by Teijin DuPont Films Japan Limited) using a gravure roll coater. The resulting coating film had a thickness after drying of 100 nm.

A pressure-sensitive adhesive solution of 100 parts of an acrylic pressure-sensitive adhesive (SK-DYNE 1473H, manufactured by Soken Chemical & Engineering Co., Ltd.) having 1.0 part by weight of a curing agent (CORONATE L-45, manufactured by Nippon Polyurethane Industry Co., Ltd.) mixed therewith was coated on the opposite surface of the substrate film to the coating film surface using a bar coater. After drying at 100° C. for one minute, the pressure-sensitive adhesive layer had a thickness of about 10 μm. Further, a releasable film (MRF-25, manufactured by Mitsubishi Polyester Film Corporation) having a thickness of 25 μm was adhered to the surface (exposed surface) of the pressure-sensitive adhesive layer.

### Comparative Example 2

A commercially available ultraviolet light-curable silicone solution was coated on one surface of a polyester based film having a thickness of 38 μm (PET-SL, manufactured by Teijin DuPont Films Japan Limited) using a gravure roll coater and irradiated with ultraviolet light for 30 seconds to form a cured film. The resulting coating film had a thickness of 100 nm.

A pressure-sensitive adhesive solution of 100 parts of an acrylic pressure-sensitive adhesive (SK-DYNE 1473H, manufactured by Soken Chemical & Engineering Co., Ltd.) having 1.0 part by weight of a curing agent (CORONATE L-45, manufactured by Nippon Polyurethane Industry Co., Ltd.) mixed therewith was coated on the opposite surface of the film to the coating film surface using a bar coater. After drying at 100° C. for one minute, the pressure-sensitive adhesive layer had a thickness of about 10 μm. Further, a releasable film (MRF-25, manufactured by Mitsubishi Polyester Film Corporation) having a thickness of 25 μm was adhered to the surface (exposed surface) of the pressure-sensitive adhesive layer.

The surface protective films obtained in Examples 1 to 2 and Comparative Examples 1 to 2 were each evaluated with respect to antistaining property and ink adhesiveness.

Antistaining property

A pressure-sensitive adhesive solution of 100 parts by weight of an acrylic pressure-sensitive adhesive (SK-DYNE 1473H, manufactured by Soken Chemical & Engineering Co., Ltd.) having 1.0 part by weight of a curing agent (CORONATE L-45, manufactured by Nippon Polyurethane Industry Co., Ltd.) mixed therewith was coated on the mold release treated surface of a polyester based film (E7002, manufactured by Toyobo Co., Ltd.), on one surface of which was subjected to mold release treatment, using a bar coater and dried at 100° C. for 2 minutes. The pressure-sensitive adhesive surface of the pressure-sensitive adhesive-coated film was rubbed on the coating film surface of each of the surface protective films obtained in the Examples and Comparative Examples, and only the adhered pressure-sensitive adhesive was wiped by JK WIPER 150-S manufactured by Crecia Corporation. At that time, the pressure-sensitive adhesive wiping properties were evaluated.

◯: The pressure-sensitive adhesive adhered on the surface is entirely wiped, and no wiping mark remains.

x: The pressure-sensitive adhesive remains on the coating film surface and is not completely wiped.

Ink Adhesiveness

A quick-drying round stamp No. 11 (color tone: red) manufactured by Shachihata Inc. was sealed on the coating film surface of each of the surface protective films obtained in the Examples and Comparative Examples. After standing at room temperature for 5 minutes, the sealed ink was wiped by JK WIPER 150-S manufactured by Crecia Corporation. At that time, the degree of dropping of the ink was evaluated.

◯: The shape where the ink is sealed remains as it is.

x: A part or the whole of the ink drops.

The evaluation results by the above evaluation methods are shown in Table 1 below.

TABLE 1

| | Antistaining property | Ink adhesiveness |
|---|---|---|
| Example 1 | ◯ | ◯ |
| Example 2 | ◯ | ◯ |
| Comparative | X | ◯ |
| Example 1 | | |
| Comparative | ◯ | X |
| Example 2 | | |

### Example 3

A pressure-sensitive adhesive solution of 100 parts of an acrylic pressure-sensitive adhesive (SK-DYNE 1496, manufactured by Soken Chemical & Engineering Co., Ltd.) having 0.8 parts by weight of a curing agent (D-90, manufactured by Soken Chemical & Engineering Co., Ltd.) and 0.08 parts by weight of an accelerator (ACCELERATOR-S, manufactured by Soken Chemical & Engineering Co., Ltd.) mixed therewith was coated on the antistatic treated surface of an antistatic polyester based film having a thickness of 38 μm (T100Q manufactured by Mitsubishi Polyester Film Corporation) using a bar coater and dried at 100° C. for one minute. The pressure-sensitive adhesive layer after drying had a thickness of about 18 μm.

Further, a releasable film (MRF-25, manufactured by Mitsubishi Polyester Film Corporation) having a thickness of 25 μm was stuck onto the surface (exposed surface) of the pressure-sensitive adhesive layer.

A surfactant made of an ammonium salt of a fluorine based phosphoric acid ester (DAIFREE ME-313, manufactured by Daikin Industries, Ltd.) was coated in a thickness of coating film after drying of 50 nm on the opposite surface of the substrate film to the surface of the pressure-sensitive adhesive layer using a gravure roll coater and heated at a temperature of 100° C. for several seconds to eliminate the diluting solvent. Further, an antistatic agent SAT-4 (manufactured by Nihon Pharmaceutical Co., Ltd.) was blown in the mist-like state onto the releasable film surface of the surface protective film using a mist blower manufactured by Tect Co., Ltd.

### Example 4

A protective film was prepared in the same manner as in Example 3, except that a surfactant made of an ammonium salt of a fluorine based phosphoric acid ester (a lower layer of a two-layer separated solution of DAIFREE ME-414, manufactured by Daikin Industries, Ltd.) was coated in a thickness of coating film after drying of 50 nm on the opposite surface of the substrate film to the pressure-sensitive adhesive-coated surface using a gravure roll coater.

### Example 5

A protective film was prepared in the same manner as in Example 3, except that a surfactant made of an ammonium salt of a fluorine based phosphoric acid ester (DAIFREE ME-3 13, manufactured by Daikin Industries, Ltd.) was coated in a thickness of coating film after drying of 50 nm on the opposite surface of the substrate film to the pressure-sensitive adhesive-coated surface by the mist method.

### Example 6

A protective film was prepared in the same manner as in Example 3, except that a surfactant made of an ammonium salt of a fluorine based phosphoric acid ester (a lower layer of a two-layer separated solution of DAIFREE ME-414, manufactured by Daikin Industries, Ltd.) was coated in a thickness of coating film of 50 nm on the opposite surface of the substrate film to the pressure-sensitive adhesive-coated surface by the mist method.

### Comparative Example 3

A protective film was prepared in the same manner as in Example 3, except that a commercially available ultraviolet light-curable silicone solution was coated on the opposite surface of the substrate film to the pressure-sensitive adhesive-coated surface using a gravure roll coater and irradiated with ultraviolet light for 30 seconds to form a cured film. The resulting coating film had a thickness of 50 nm.

### Comparative Example 4

A protective film was prepared in the same manner as in Example 3, except that a commercially available ultraviolet light-curable silicone solution was coated on the opposite surface of the substrate film to the pressure-sensitive adhesive-coated surface in the mist method and irradiated with ultraviolet light for 30 seconds to form a cured film. The resulting coating film had a thickness of 50 nm.

### Comparative Example 5

A protective film was prepared in the same manner as in Example 3, except that a commercially available a long chain alkyl group based mold release treating agent (a dialkylsulfosuccinic acid ester salt) was coated in a thickness of coating film after drying of 50 nm on the opposite surface of the substrate film to the pressure-sensitive adhesive-coated surface using a gravure roll.

### Comparative Example 6

A protective film was prepared in the same manner as in Example 3, except that a commercially available a long chain alkyl group based mold release treating agent was coated in a thickness of coating film after drying of 50 nm on the opposite surface of the substrate film to the pressure-sensitive adhesive-coated surface by the mist method.

The protective films obtained in Examples 3 to 6 and Comparative Examples 3 to 6 were each evaluated with respect to the cohesion, antistaining property and ink adhesiveness.

Evaluation of Cohesion

The broken state was evaluated according to the following criteria.

A: Cohesion and breakage within the surfactant layer

After peeling away the pressure-sensitive adhesive tape, the surfactant component was confirmed on both the treated surface of the surface treated film and the pressure-sensitive adhesive surface of the pressure-sensitive adhesive tape.

B: Interfacial breakage at the interface between the surfactant and the substrate film

After peeling away the pressure-sensitive adhesive tape, the surfactant component was confirmed only in the pressure-sensitive adhesive tape side.

C: No breakage between the layers and within the layer

After peeling away the pressure-sensitive adhesive tape, the surfactant component was confirmed only in the treated surface side of the surface treated film.

The evaluation results by the above evaluation methods are shown in Table 2 below.

TABLE 2

| | Evaluation of | Antistaining | Ink |
|---|---|---|---|
| | cohesion | property | adhesiveness |
| Example 3 | A | ◯ | ◯ |
| Example 4 | A | ◯ | ◯ |
| Example 5 | A | ◯ | ◯ |
| Example 6 | A | ◯ | ◯ |
| Comparative | C | ◯ | X |
| Example 3 | | | |
| Comparative | B | ◯ | X |
| Example 4 | | | |
| Comparative | C | ◯ | X |
| Example 5 | | | |
| Comparative | A | X | ◯ |
| Example 6 | | | |

### Example 7

A pressure-sensitive adhesive solution of 100 parts of an acrylic pressure-sensitive adhesive (SK-DYNE 1496, manufactured by Soken Chemical & Engineering Co., Ltd.) having 0.8 parts by weight of a curing agent (D-90, manufactured by Soken Chemical & Engineering Co., Ltd.) and 0.08 parts by weight of an accelerator (ACCELERATOR-S, manufactured by Soken Chemical & Engineering Co., Ltd.) mixed therewith was coated on the antistatic treated surface of an antistatic polyester based film having a thickness of 38 μm (T100G, manufactured by Mitsubishi Polyester Film Corporation) using a bar coater and dried at 100° C. for one minute. The pressure-sensitive adhesive layer after drying had a thickness of about 18 μm. Further, a releasable film (MRF-25, manufactured by Mitsubishi Polyester Film Corporation) having a thickness of 25 μm was adhered to the surface (exposed surface) of the pressure-sensitive adhesive layer.

An emulsion of dimethyl silicone oil (TSM6344, manufactured by GE Toshiba Silicones Co., Ltd.) was diluted 15 times with a solution of water/isopropyl alcohol in a volume ratio of 70/30 and coated in a thickness of coating film after drying of 80 nm on the opposite surface of the substrate film to the pressure-sensitive adhesive-coated surface using a gravure roll coater and heated at a temperature of 100° C. for several seconds to eliminate the diluting solvent. Further, an antistatic agent SAT-4 (manufactured by Nihon Pharmaceutical Co., Ltd.) was blown in the mist-like state onto the releasable film surface of the protective film using a mist blower manufactured by Tect Co., Ltd.

### Example 8

A protective film was prepared in the same manner as in Example 7, except that an emulsion of dimethyl silicone oil (TSM6344, manufactured by GE Toshiba Silicones Co., Ltd.) was coated in a thickness of coating film of 50 nm on the opposite surface of the substrate film to the pressure-sensitive adhesive-coated surface by the mist method.

### Comparative Example 7

A protective film was prepared in the same manner as in Example 7, except that a commercially available a long chain alkyl group based mold release treating agent was coated in a thickness of coating film of 50 nm on the opposite surface of the substrate film to the pressure-sensitive adhesive-coated surface using a gravure roll.

### Comparative Example 8

A protective film was prepared in the same manner as in Example 7, except that a fluorine based surfactant (ELASGUARD 180, manufactured by Dai-ichi Kogyo Seiyaku Co., Ltd.) was coated in a thickness of coating film of 50 nm on the opposite surface of the substrate film to the pressure-sensitive adhesive-coated surface by the mist method.

The protective films obtained in Examples 7 to 8 and Comparative Examples 7 to 8 were each evaluated with respect to the cohesion, antistaining property and ink adhesiveness in the same manners as described previously, the results of which are shown in Table 3.

TABLE 3

| | Evaluation of | Antistaining | Ink |
|---|---|---|---|
| | cohesion | property | adhesiveness |
| Example 7 | A | ◯ | ◯ |
| Example 8 | A | ◯ | ◯ |
| Comparative | C | ◯ | X |
| Example 7 | | | |
| Comparative | A | X | ◯ |
| Example 8 | | | |

### Example 9

A pressure-sensitive adhesive solution of 100 parts of an acrylic pressure-sensitive adhesive (SK-DYNE 1496, manufactured by Soken Chemical & Engineering Co., Ltd.) having 0.8 parts by weight of a curing agent (D-90, manufactured by Soken Chemical & Engineering Co., Ltd.) and 0.08 parts by weight of an accelerator (ACCELERATOR-S, manufactured by Soken Chemical & Engineering Co., Ltd.) mixed therewith was coated on the antistatic treated surface of an antistatic polyester based film having a thickness of 38 μm (T100G, manufactured by Mitsubishi Polyester Film Corporation) using a bar coater and dried at 100° C. for one minute. The pressure-sensitive adhesive layer after drying had a thickness of about 18 μm. Further, a releasable film (MRF-25, manufactured by Mitsubishi Polyester Film Corporation) having a thickness of 25 μm was adhered to the surface (exposed surface) of the pressure-sensitive adhesive layer.

An emulsion of a water-soluble urethane resin (ELASTRON H-3, manufactured by Dai-ichi Kogyo Seiyaku Co., Ltd., solids content: 22.9%) was mixed with an emulsion of dimethyl silicone oil (TSM6344, manufactured by GE Toshiba Silicones Co., Ltd., solids content: 30%) having been diluted 15 times with a solution of water/isopropyl alcohol in a volume ratio of 70/30 in a ratio of the water-soluble urethane resin to dimethyl silicone of 6 times, and the mixture was coated in a thickness of coating film after drying of 80 nm on the opposite surface of the substrate film to the pressure-sensitive adhesive-coated surface using a gravure roll coater, followed by heating at a temperature of 100° C. for several seconds to eliminate the diluting solvent. Further, an antistatic agent SAT-4 (manufactured by Nihon Pharmaceutical Co., Ltd.) was blown in the mist-like state onto the releasable film surface of the protective film using a mist blower manufactured by Tect Co., Ltd.

### Example 10

A protective film was prepared in the same manner as in Example 9, except that an emulsion of a water-soluble urethane resin (ELASTRON H-3, manufactured by Dai-ichi Kogyo Seiyaku Co., Ltd.) was mixed with an emulsion of dimethyl silicone oil (TSM6344, manufactured by GE Toshiba Silicones Co., Ltd.) in a ratio of the water-soluble urethane resin to dimethyl silicone of 6 times, and the mixture was coated in a thickness of coating film of 50 nm on the opposite surface of the substrate film to the pressure-sensitive adhesive-coated surface in the mist method.

### Comparative Example 9

A protective film was prepared by coating a pressure-sensitive adhesive on one surface of a substrate film, on the opposite surface thereof to the coated surface being not subjected to any treatment.

The protective films obtained in Examples 9 to 10 and Comparative Example 9 were each evaluated with respect to the cohesion, antistaining property and ink adhesiveness in the same manners as described previously, the results of which are shown in Table 4 below.

TABLE 4

| | Evaluation of | Antistaining | Ink |
|---|---|---|---|
| | cohesion | property | adhesiveness |
| Example 9 | A | ◯ | ◯ |
| Example 10 | A | ◯ | ◯ |
| Comparative | — | X | ◯ |
| Example 9 | | | |

### Example 11

A pressure-sensitive adhesive solution of 100 parts of an acrylic pressure-sensitive adhesive (SK-DYNE 1496, manufactured by Soken Chemical & Engineering Co., Ltd.) having 0.8 parts by weight of a curing agent (D-90, manufactured by Soken Chemical & Engineering Co., Ltd.) and 0.08 parts by weight of an accelerator (ACCELERATOR-S, manufactured by Soken Chemical & Engineering Co., Ltd.) mixed therewith was coated on the antistatic treated surface of an antistatic polyester based film having a thickness of 38 μm( T100G, manufactured by Mitsubishi Polyester Film Corporation) using a bar coater and dried at 100° C. for one minute. The pressure-sensitive adhesive layer after drying had a thickness of about 18 μm. Further, a releasable film (MRF-25, manufactured by Mitsubishi Polyester Film Corporation) having a thickness of 25 μm was stuck onto the surface (exposed surface) of the pressure-sensitive adhesive layer. Thereafter, a surfactant made of an ammonium salt of a fluorine based phosphoric acid ester (DAIFREE ME-313, manufactured by Daikin Industries, Ltd.) was coated in a thickness of coating film after drying of 50 nm on the both surfaces of the releasable film/pressure-sensitive adhesive layer/antistatic polyester based film using a gravure roll coaler and heated at a temperature of 100° C. for several seconds to eliminate the diluting solvent.

### Example 12

A pressure-sensitive adhesive solution of 100 parts of an acrylic pressure-sensitive adhesive (SK-DYNE 1496, manufactured by Soken Chemical & Engineering Co., Ltd.) having 0.1 parts by weight of a curing agent (L-45, manufactured by Soken Chemical & Engineering Co., Ltd.) mixed therewith was coated on the antistatic treated surface of an antistatic polyester based film having a thickness of 38 μm (G2P8, manufactured by Teijin DuPont Films Japan Limited) using a bar coater and dried at 100° C. for one minute. The pressure-sensitive adhesive layer after drying had a thickness of about 18 μm. Further, a releasable film E7002, manufactured by Toyobo Co., Ltd.) having a thickness of 25 μm was adhered to the surface (exposed surface) of the pressure-sensitive adhesive layer. Thereafter, a surfactant made of an ammonium salt of a fluorine based phosphoric acid ester (DAIFREE ME-313, manufactured by Daikin Industries, Ltd.) was coated in a thickness of coating film after drying of 50 nm on the opposite surface of the substrate film to the surface of the pressure-sensitive adhesive layer using a gravure roll coater and heated at a temperature of 100° C. for several seconds to eliminate the diluting solvent.

### Example 13

A pressure-sensitive adhesive solution of 100 parts of an acrylic pressure-sensitive adhesive (SK-DYNE 1496, manufactured by Soken Chemical & Engineering Co., Ltd.) having 0.1 parts by weight of a curing agent (L-45, manufactured by Soken Chemical & Engineering Co., Ltd.) mixed therewith was coated on the antistatic treated surface of an antistatic polyester based film having a thickness of 38 μm (G2P8, manufactured by Teijin DuPont Films Japan Limited) using a bar coater and dried at 100° C. for one minute. The pressure-sensitive adhesive layer after drying had a thickness of about 18 μm. Further, a releasable film (E7002, manufactured by Toyobo Co., Ltd.) having a thickness of 25 μm was stuck onto the surface (exposed surface) of the pressure-sensitive adhesive layer. Thereafter, a surfactant made of an ammonium salt of a fluorine based phosphoric acid ester (DAIFREE ME-313, manufactured by Daikin Industries, Ltd.) was coated in a thickness of coating film after drying of 50 nm on the opposite surface of the substrate film to the surface of the pressure-sensitive adhesive layer using a gravure roll coater and heated at a temperature of 100° C. for several seconds to eliminate the diluting solvent.

The protective films prepared in Examples 11 to 13 were subjected to the following tests.

Evaluation of Solvent Resistance

Each of the protective films was measured for static decay before and after wiping the base surface side of the film with ethanol. The static decay was determined by forcibly applying 5,000V to the film using Static Decay Meter, Model 406C manufactured by ETS Inc. and measuring a static decay time until the electricity was decayed to 1% according to ML-B-81705B.

◯: Accepted for the ML standards

×: Not accepted for the ML standards

The measurement results are shown in Table 5 below.

Cellophane Tape Peeling Strength

Cellotape (width: 24 mm) manufactured by Nichiban Co., Ltd. was adhered to the base surface side of the protective film, and the 180° peeling strength of Cellotape was measured at a peeling rate of 300 mm/min.

◯: The 180° peeling strength was larger than 400 g/24 mm-width.

×: The 180° peeling strength was 400 g/24 mm-width or lower.

The measurement results are shown in Table 6 below.

Cue Releasability:

The protective film was adhered to a polarizing plate via the pressure-sensitive adhesive layer, and Cellotape (width: 24 mm) manufactured by Nichiban Co., Ltd. was adhered to the base surface side of the protective film, thereby evaluating the protective film for cue releasability.

◯: The protective film could be peeled away without release of Cellotape from the protective film.

×: Cellotape released from the protective film, whereby the protective film could not be peeled away.

The measurement results are shown in Table 6 below.

TABLE 5

| | Example 11 | Example 12 | Example 13 |
|---|---|---|---|
| Before wiping with | ◯ | ◯ | ◯ |
| solvent | | | |
| After wiping with | ◯ | ◯ | ◯ |
| solvent | | | |

TABLE 6

| | Example 11 | Example 12 | Example 13 |
|---|---|---|---|
| Peeling strength | ◯ | ◯ | ◯ |
| Cue releasability | ◯ | ◯ | ◯ |

### INDUSTRIAL APPLICABILITY

A surface protective film comprising a substrate film having a specific coating film formed on the outermost surface thereof is excellent in antistaining property and ink adhesiveness. Accordingly, the surface protective film can be suitably used for surface protection of polarizing plates, liquid crystal displays, plasma displays, etc.

1. A surface protective film comprising a substrate film having formed on one surface thereof a coating film selected from the group consisting of (1) a coating film of a nonionic surfactant having a hydrophilic-lipophilic balance (HLB) of 13 or more, (2) a coating film of a surfactant comprising an ammonium salt of a fluorine based phosphoric acid ester, (3) a coating film of dimethyl silicone oil, and (4) a coating film of a mixture of a water-soluble urethane resin and dimethyl silicone.

2. The surface protective film according to claim 1, wherein the substrate film comprises a thermoplastic resin.

3. The surface protective film according to claim 1, wherein the substrate film is a polyester film.

4. The surface protective film according to claim 1, wherein the nonionic surfactant is a fatty acid ester.

5. The surface protective film according to claim 1, having a layer of a pressure-sensitive adhesive on the surface of the substrate film opposite the coating film.

6. The surface protective film according to claim 5, wherein the pressure-sensitive adhesive is an acrylic pressure-sensitive adhesive.

7. The surface protective film according to claim 6, wherein the pressure-sensitive adhesive contains a plasticizer.

8. The surface protective film according to claim 5, having an interlayer between the substrate film and the pressure-sensitive adhesive layer.

9. The surface protective film according to claim 8, wherein the coating film has a cellophane tape peeling strength of larger than 400 g/24 mm.

10. The surface protective film according to claim 5, wherein a releasable film is adhered on the exposed surface of the pressure-sensitive adhesive layer.

11. The surface protective film according to claim 10, wherein the releasable film is a silicone mold release treating agent-coated polyester film

12. The surface protective film according to claim 10, wherein an antistatic substance is coated on the surface of the releasable film.

13. The surface protective film according to claim 1, which is adhered on the surface of a polarizing plate.

14. The surface protective film according to claim 1, which is used for polarizing plate.
